(19) United States
(12) Patent Application Publication
(10) Pub. No.: US 2026/0302736 A1
(43) Pub. Date: Oct. 1, 2026

(54) ELECTRICAL INSTALLATION FOR AN AIRCRAFT COMPRISING A CURRENT TRANSFORMER FOR A DISTRIBUTION BAR AND AIRCRAFT COMPRISING SUCH AN INSTALLATION

(71) Applicant: Airbus Operations SAS, TOULOUSE (FR)

(72) Inventors: Matthieu DE KERGOMMEAUX, TOULOUSE (FR); Benjamin BOISNIER, TOULOUSE (FR)

(21) Appl. No.: 19/631,034

(22) Filed: Mar. 27, 2026

(30) Foreign Application Priority Data
Mar. 28, 2025 (FR) FR2503196

(51) Int. Cl. H02B 1/20; B64D 41/00; H02B 1/04

(52) U.S. Cl. CPC H02B 1/20; B64D 41/00; H02B 1/04; B64D 2221/00

(57) ABSTRACT

An electrical installation for an aircraft with: an electrical distribution bar intended to be fastened to a support of an electrical cabinet; a printed circuit which has a first electrical connection element; a current transformer having a body, a fastener to fasten the body to the support; and a second electrical connection element to cooperate with the first electrical connection element of the printed circuit; and, an item of equipment intended to be electrically connected to the distribution bar. Also an aircraft with such an electrical installation.

### CROSS-REFERENCES TO RELATED APPLICATIONS

This application claims the benefit of French Patent Application Number FR2503196, filed on Mar. 28, 2025, the entire disclosure of which is incorporated herein by way of reference.

### FIELD OF THE INVENTION

The present invention relates to an electrical installation for an aircraft, comprising a current transformer intended to be used on an electrical distribution bar (also known as a busbar) and to an aircraft comprising such an electrical installation.

### BACKGROUND

Aircraft are generally equipped with wiring harnesses comprising electrical cables C1 which pass through current transformers T generally disposed in electrical systems or cabinets. Some of these transformers can for example be used to carry out current measurements. With the increase in electrical and electronic equipment on board aircraft, the number of electrical cabinets has increased, as has the number of electrical cables C1 and transformers T.

A drawback of this solution lies in the fact that the overall electrical wiring is complex and bulky. In addition, the fastening of the electrical cables C1 to the transformers T is time-consuming for the operators and the maintenance operations (fault diagnosis and repair for example) are complex.

Thus, there is therefore a need to provide an electrical wiring solution that addresses at least some of these drawbacks. In particular, there is therefore a need to provide an electrical wiring solution that is simple to implement, reliable and secure for operators in particular.

### SUMMARY OF THE INVENTION

An object of the present invention is to propose an electrical installation for an aircraft, proposing an electrical wiring solution which is notably simple to implement, reliable and secure for operators.

To this end, an electrical assembly for an aircraft is proposed, comprising:
an electrical distribution bar intended to be fastened to a support of an electrical cabinet;
a printed circuit comprising a first male or female electrical connection element;
a current transformer comprising:
   a body comprising a through-opening, said distribution bar being arranged to pass through said through-opening;
   fastening means intended to fasten said body to said support; and
   a second female or male electrical connection element disposed in said through-opening and electrically connected to said corresponding first male or female electrical connection element of said printed circuit; and,
an item of equipment intended to be electrically connected to said distribution bar.

In this way, the invention proposes a solution which makes it possible to simplify the overall electrical wiring of an aircraft while optimizing its bulkiness. Specifically, the use of electrical distribution bars makes it possible to simplify the wiring of electrical cabinets and has an optimized bulk. In addition, since the electrical wiring is simplified, maintenance operations are simplified. Such an electrical installation also makes it possible to increase the reliability of the installation.

According to a particular aspect of the invention, said current transformer comprises a switching device configured to detect whether said item of equipment is electrically connected to said distribution bar.

According to a first exemplary embodiment of the invention, said switching device comprises a mechanical switch and a proximity sensor disposed in said body and in proximity to said through-opening and said first electrical connection element. Said mechanical switch comprises:
a cap mounted movably in translation in said through-opening in said body between a retracted position, corresponding to a position in which said item of equipment is electrically connected to said distribution bar, and a deployed position, corresponding to a position in which said item of equipment is not electrically connected to said distribution bar; and,
an elastic element secured to said body and said cap, said elastic element being configured to move said cap from said retracted position to said deployed position when said item of equipment is not electrically connected to said distribution bar.

In particular, said proximity sensor is intended to detect when said cap is in said retracted position and is configured to transmit information about the electrical connection of said item of equipment to a control unit for controlling the electrical power supply of said distribution bar.

According to a second exemplary embodiment of the invention, said switching device comprises a mechanical switch and an electrical contactor secured to said second electrical connection element, said mechanical switch comprising:
a cap mounted movably in translation in said through-opening in said body between a retracted position, corresponding to a position in which said item of equipment is electrically connected to said distribution bar, and a deployed position, corresponding to a position in which said item of equipment is not electrically connected to said distribution bar, said cap having a switching pin; and,
an elastic element secured to said body and said cap, said elastic element being configured to move said cap from said retracted position to said deployed position when said item of equipment is not electrically connected to said distribution bar.

In particular, said electrical contactor is intended to cooperate with said switching pin of said cap when the latter is in the retracted position and said electrical contactor is then configured to transmit an electrical signal to a control unit for controlling the electrical power supply of said distribution bar corresponding to the electrical connection of said item of equipment to the distribution bar.

According to a particular aspect of the invention, said mechanical switch further comprises holding means configured to hold said cap in said through-opening.

According to yet another particular aspect of the invention, said cap comprises a main part of tubular shape, a first end of which comprises a peripheral edge received in said through-opening, said through-opening comprising, at a first end, a peripheral slot and, at a second end, a peripheral shoulder, said holding means comprising a locking washer disposed in said peripheral slot, and said peripheral edge of said cap being intended to move between said peripheral shoulder of said through-opening and said locking washer.

Furthermore, in the second exemplary embodiment, said cap comprises a switching pin which extends from the peripheral edge in a direction opposite to said main part, said switching pin being configured to pass through said holding means so as to cooperate with said electrical contactor when said cap is in the retracted position.

According to a particular aspect of the invention, said elastic element is disposed between said locking washer and said peripheral edge of said cap.

The invention also relates to an aircraft comprising at least one electrical installation as described above.

### BRIEF DESCRIPTION OF THE DRAWINGS

The abovementioned features of the invention, along with others, will become more clearly apparent upon reading the following description of one exemplary embodiment, said description being given with reference to the appended drawings, in which:

FIG. 1 is a top view of an aircraft implementing the invention;

FIG. 2 is an exploded, perspective view partially illustrating an electrical installation according to a first exemplary embodiment of the invention;

FIG. 3 is a partially assembled, perspective view illustrating the installation in FIG. 2;

FIG. 4 is a view from below and in section of the installation in FIG. 2 with the switch in the deployed position;

FIG. 5 is a view from below and in section of the installation in FIG. 2 with the switch in the retracted position;

FIG. 6 is a view from below and in section of an installation according to a second exemplary embodiment, in which the switch is in the deployed position; and

FIG. 7 is a view from below and in section of the installation in FIG. 6 with the switch in the retracted position.

### DETAILED DESCRIPTION OF AN EXEMPLARY EMBODIMENT

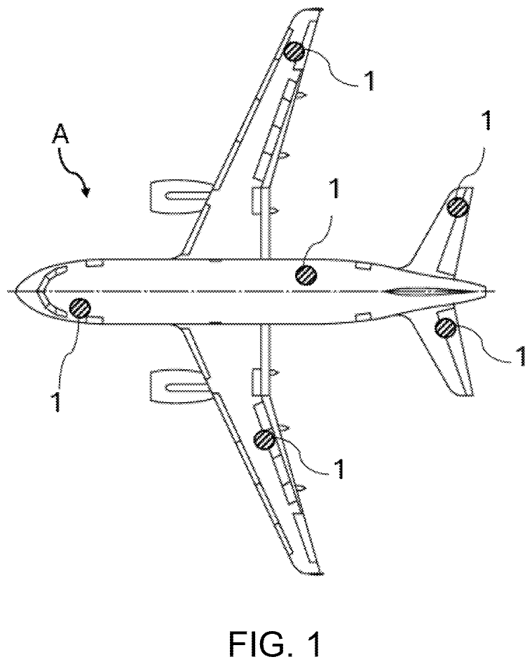

FIG. 1 illustrates, in a top view, an aircraft A which comprises at least one electrical installation according to the invention. The use of such an electrical installation in a plane makes it possible, as described below, to optimize the bulk of such an installation and to provide an installation that is simple to implement, reliable and secure for operators.

FIGS. 1 to 7 illustrate exemplary embodiments of an electrical installation 1 according to the invention which is intended to be implemented in an aircraft A. Unlike the prior art, the electrical installation 1 according to the invention no longer uses a wiring harness comprising a plurality of electrical cables but uses a system of electrical distribution bars.

Thus, the electrical installation 1 comprises an electrical distribution bar 11 intended to be fastened to a support 101 of an electrical cabinet (not illustrated). The distribution bar 11 may be flush or project with respect to the support 101 of the electrical cabinet. The support 101 may, for example, be an internal or external element of the electrical cabinet. It may, for example, be manufactured from metal or composite.

An item of equipment 16, which in this example is in the form of an electrical cabinet door, is intended to be electrically connected to the distribution bar 11. Thus, when the door 16 is electrically connected to the distribution bar 11, the distribution bar 11 is intended to supply electrical power to the electrical cabinet door 16 (as illustrated schematically in FIGS. 5 and 7) so as to operate any electrical components/equipment of this door 16.

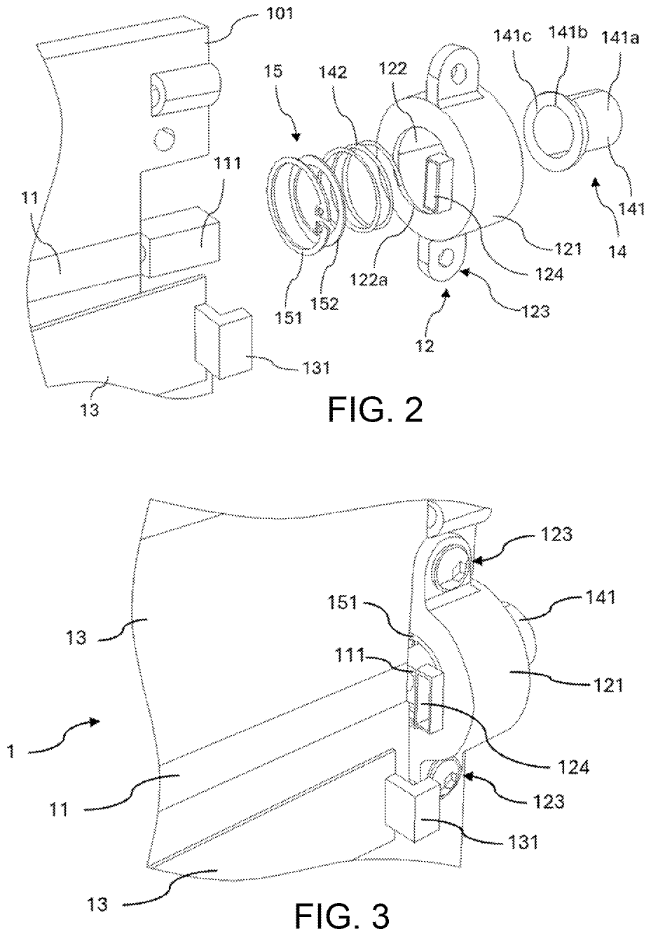

The electrical installation 1 further comprises a printed circuit 13 which comprises a first male (or female) electrical connection element 131. In FIGS. 2 and 3, the first electrical connection element 131 is not shown assembled. For reasons of bulk, the printed circuit 13 may be fastened to said distribution bar 11.

In addition, the electrical installation 1 comprises a current transformer 12 which comprises a body 121 having a through-opening 122. In this example, the body 121 has a generally circular shape and the through-opening 122 also has a circular shape. Here, the through-opening 122 extends generally coaxially with the longitudinal axis of the body 121. The distribution bar 11 is arranged to pass through the through-opening 122 in the body 121. In this way, the current transformer 12 can be used to measure the current passing through the distribution bar 11 when the door 16 is connected to the distribution bar 11.

The current transformer 12 comprises fastening means 123 intended to fasten the body 121 to the support 101. In this example, the body 121 has holes disposed in protuberances and the fastening means 123 are in the form of a fastening screw which passes through the holes in the body 121 and which is fastened in the support 101 of the electrical cabinet. Of course, other types of fastening means 123 can be envisioned without departing from the general principle of the invention.

The current transformer 12 further comprises a second female (or male if the first connection element 131 of the printed circuit is a female element) electrical connection element 124 disposed in the through-opening 122. The second electrical connection element 124 cooperates with the corresponding first electrical connection element 131 of the printed circuit 13 so as to ensure an electrical connection between the current transformer 12 and the printed circuit 13.

In particular, the printed circuit 13 notably makes it possible to collect the measurement data regarding the current passing through the distribution bar 11 which are recorded by the current transformer 12. These measurement data can be fed back, by virtue of the printed circuit 13, to a management system (not illustrated) of the electrical installation 1. As detailed below, the printed circuit 13 can also be used to transfer a signal indicating the state of the connection between the distribution bar 11 and the door 16 (for example in order to determine whether the door 16 of the electrical cabinet is open or closed).

Reference is made here to a single distribution bar 11 and a single current transformer 12, but it will of course be understood that the electrical installation of the invention may comprise a plurality of distribution bars 11 and current transformers 12.

The invention therefore proposes an electrical installation 1 which makes it possible to simplify the overall electrical wiring of the aircraft A while optimizing its bulkiness. Specifically, the use of electrical distribution bars makes it possible to simplify the wiring of electrical cabinets and has a smaller bulk than wiring by conventional electrical wires.

In addition, since the electrical wiring is simplified, maintenance operations (for example fault diagnosis or replacement of a current transformer) are simplified.

Such an electrical installation 1 also makes it possible to increase the reliability of the installation since the risks of accidental disconnection of an electrical cable are eliminated, as are the risks of short circuits associated with an accidentally stripped cable.

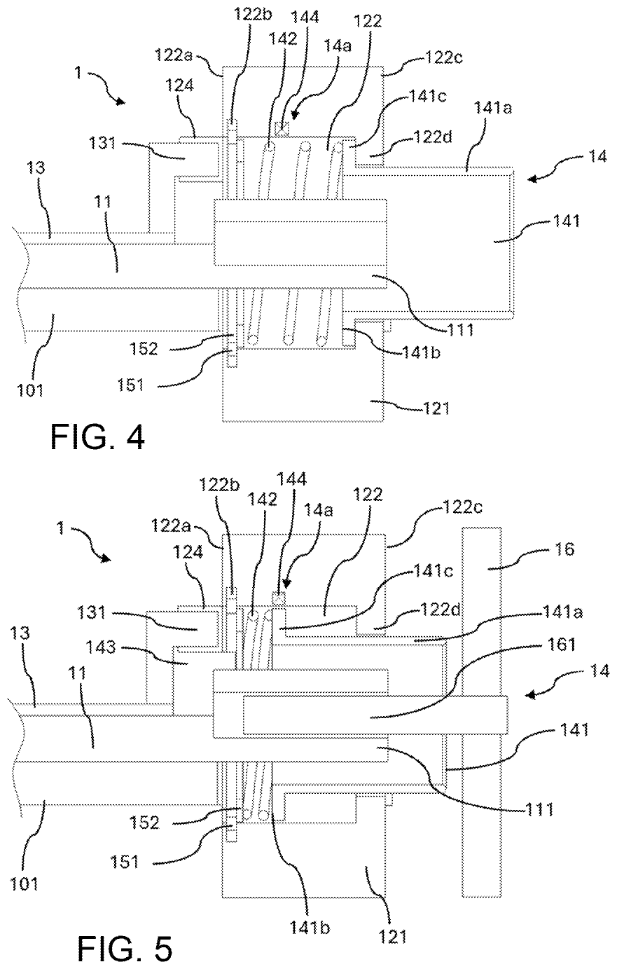

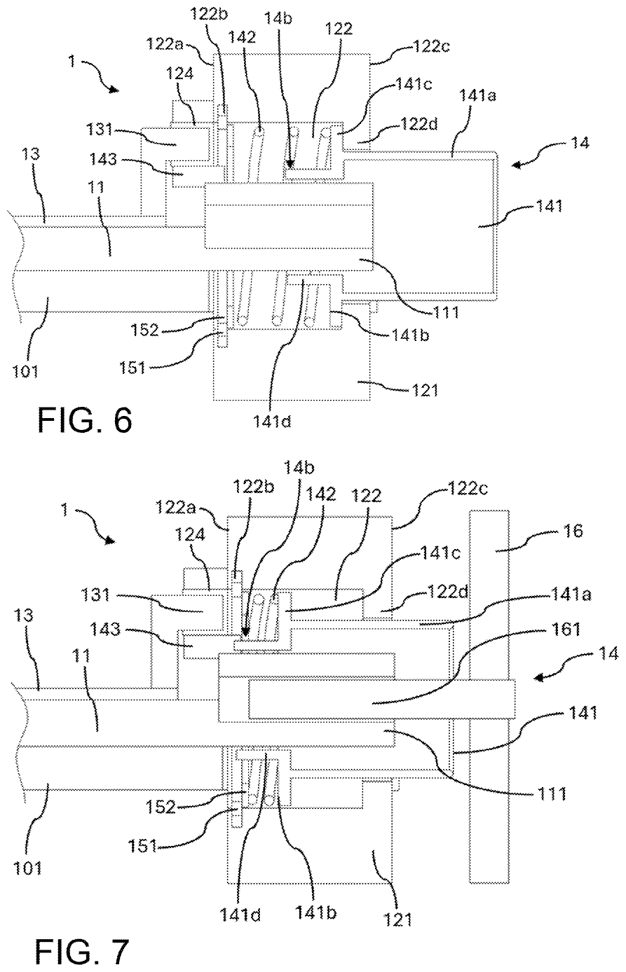

Preferably, the current transformer 12 comprises a switching device 14a (FIG. 4 and 5) or 14b (FIGS. 6 and 7) configured to detect whether the item of equipment 16 (here the door 16) is electrically connected to the distribution bar 11. In other words, the switching device 14a, 14b acts as a sensor for determining whether the door 16 of the electrical installation 1 is open or closed, thus making it possible to supply or not supply electricity to the distribution bar 11.

According to the first exemplary embodiment illustrated in FIGS. 2 to 5, the switching device 14a comprises a mechanical switch 14 and a proximity sensor 144 which is here disposed in the body 121 and in proximity to the through-opening 122. Also preferably, the proximity sensor 144 is disposed in proximity to the first electrical connection element 131 because it is generally at this location that the cap (described below) is located when it is in the retracted position. The proximity sensor 144 is electrically connected to the printed circuit 13 such that the printed circuit 13 is able to know the state of the proximity sensor 144.

In particular, the mechanical switch 14 comprises a cap 141 mounted movably in translation in the through-opening 122 in the body 121 between a retracted position, corresponding to a position in which the door 16 is electrically connected to the distribution bar 11, and a deployed position, corresponding to a position in which the door 16 is not electrically connected to the distribution bar 11. In this example, the cap 141 has a generally tubular shape with a circular section corresponding to the shape of the through-opening 122 in the body 121.

The mechanical switch 14 also comprises an elastic element 142 secured to the body 121 and to the cap 141. The elastic element 142, in this example in the form of a spring, is configured to move the cap 141 from the retracted position to the deployed position when the door 16 is not electrically connected to the distribution bar 11. In other words, the elastic element 142 exerts a predetermined force on the cap 141 making it possible to hold the cap 141 in the deployed position or, when the cap 141 is in the retracted position, to move the cap 141 toward the deployed position. When an opposing force greater than the predetermined force exerted by the elastic element 142 is applied to the cap 141, then the cap 141 is moved from the deployed position to the retracted position (this opposing force may for example be applied by an operator or simply by the closed door 16 of the electrical cabinet).

The proximity sensor 144 is intended to detect when the cap 141 is in the retracted position, this corresponding to the closed position of the door 16 and therefore to the electrical connection of the door 16 with the distribution bar 11. In other words, the proximity sensor 144 is positioned such that the latter is capable of detecting when the cap 141 is retracted. This detection of the cap 141 in the retracted position by the proximity sensor 144 makes it possible for the latter to transmit information about the electrical connection of the door 16 to the distribution bar to a control unit (not illustrated) which can then control whether or not electricity is supplied to the distribution bar 11.

Thus, it is possible to simply and reliably detect whether the door 16 is electrically connected to the distribution bar 11 depending on the position of the movable cap 141. The control unit can therefore, in the event of detection of an open door 16 (corresponding to electrical non-connection of the door 16 to the distribution bar 11) cut the electrical power supply of the distribution bar 11 so as to ensure the safety of an operator wishing to perform a maintenance operation on the electrical installation 1.

In addition, the cap 141 acts as a protective element preventing direct contact with the live distribution bar 11, for example.

More specifically here, the door 16 comprises a connection element 161 (for example in the form of a stud, a pin, a shaft or the like) intended to pass through the cap 141 and to cooperate with a corresponding connection element 111 borne by the distribution bar 11. In this way, the distribution bar 11 can supply electricity to any electrical components/equipment of the door 16. When the door 16 of the electrical cabinet (not illustrated in FIG. 4) is open, the cap 141 is in the deployed position (as illustrated in FIG. 4) because no force is applied to it. The elastic element 142 pushes back and therefore holds the cap 141 in the deployed position. There is therefore no cooperation between the connection elements 161 of the door 16 and the corresponding connection element 111 of the distribution bar 11. The proximity sensor 144 then detects that the door 16 is not electrically connected to the distribution bar 11 and this information can be transmitted by the printed circuit 13 to the control unit such that the electrical power supply of the distribution bar is cut, thus allowing the intervention of an operator without danger, for example.

When the door is closed (as illustrated in FIG. 5), the cap 141 is in the retracted position because the door 16 presses on the cap 141 and moves it from its deployed position to its retracted position. The connection element 161 of the door 16 therefore cooperates with the connection element 111 of the distribution bar 11. In addition, the proximity sensor 144 detects the cap 141 (which is not the case in the deployed position of the cap 141) and therefore the electrical connection between the door 16 and the distribution bar 11 and transmits this information to the control unit which can restore the electrical power supply of the distribution bar 11.

According to another exemplary embodiment, illustrated in FIGS. 6 and 7, the switching device 14b comprises a mechanical switch 14 and an electrical contactor 143 secured to the second electrical connection element 124. This second exemplary embodiment is therefore distinguished from the exemplary embodiment described above in that it does not comprise a proximity sensor 144 but an electrical contactor 143. Thus, the switch 14 is substantially identical to that of the first exemplary embodiment in terms of its structure and its functions, and will therefore not be described in detail again.

In this second exemplary embodiment, the cap 141 comprises a switching pin 141d which is intended to cooperate with the electrical contactor 143 when the cap 141 is in the retracted position. The electrical contactor 143 is in particular configured to transmit an electrical signal, indicating the electrical connection of the door 16 to the distribution bar 11, to the control unit (which in this example can simply be in the form of a power contactor) which controls the electrical power supply of the distribution bar 11. This electrical signal makes it possible to activate the electrical contactor such that the supply of electricity to the distribution bar is effective only when door 16 is electrically connected to the distribution bar, that is to say only when the cap 141 is in the retracted position and when the switching pin 141d cooperates with the electrical contactor 143.

As above, it is thus possible to simply and reliably detect whether the door 16 is electrically connected to the distribution bar 11 depending on the position of the movable cap 141. The control unit can therefore, in the event of detection of an open door 16 (corresponding to electrical non-connection of the door 16 to the distribution bar 11) cut the electrical power supply of the distribution bar 11 so as to ensure the safety of an operator wishing to perform a maintenance operation on the electrical installation 1. Here again, the cap 141 acts as a protective element preventing direct contact with the live distribution bar 11, for example.

As above, the door 16 comprises a connection element 161 intended to pass through the cap 141 and to cooperate with a corresponding connection element 111 borne by the distribution bar 11. The distribution bar 11 can thus supply electricity to any electrical components/equipment of the door 16. When the door 16 of the electrical cabinet (not illustrated in FIG. 6) is open, the cap 141 is in the deployed position (as illustrated in FIG. 6) because no force is applied to it. The elastic element 142 pushes back and therefore holds the cap 141 in the deployed position. There is therefore no cooperation between the connection elements 161 of the door 16 and the corresponding connection element 111 of the distribution bar 11. Since the electrical contactor 143 is not activated, this indicates that the door 16 is not electrically connected to the distribution bar 11 and no electrical signal corresponding to the electrical connection of the door 16 to the distribution bar is then transmitted to the control unit by the printed circuit 13. Thus, the electrical power supply of the distribution bar 11 is cut, thus allowing the intervention of an operator without danger, for example.

When the door is closed (as illustrated in FIG. 7), the cap 141 is in the retracted position because the door 16 presses on the cap 141 and moves it from its deployed position to its retracted position. The connection element 161 of the door 16 therefore cooperates with the connection element 111 of the distribution bar 11, just as the switching pin 141d cooperates with the electrical contactor 143. Thus, a signal regarding the connection of the door 16 to the distribution bar 11 can be transmitted from the electrical contactor 143 to the control unit via the printed circuit 13 such that the control unit can restore the electrical power supply of the distribution bar 11.

In these exemplary embodiments, the switch 14 acts as an element for detecting the opening of the door 16 as well as a protective element which makes it possible to cut the electrical power supply of the distribution bar 11 so as to avoid any risk of accident.

As illustrated in FIGS. 2 to 7, the mechanical switch 14 further comprises holding means 15 configured to hold the cap 141 in the through-opening 122 while allowing it to move between the deployed and retracted positions.

More specifically, the cap 141 comprises a main part 141a of generally tubular shape, a first end 141b of which (located on the side opposite the door 16) comprises a peripheral edge 141c received in the through-opening 122. The through-opening 122 comprises, at a first end 122a, a peripheral slot 122b and, at a second end 122c, a peripheral shoulder 122d.

The holding means 15 comprise a locking washer 151 (which here is in the form of a circlip so as to facilitate its installation) disposed in the peripheral slot 122b. Thus, the peripheral edge 141c of the cap 141 can move in the through-opening 122 between the peripheral shoulder 122d of the through-opening 122 and the locking washer 151. The peripheral shoulder 122d and the locking washer 151 therefore form stops to limit the movement of the cap 141 within the through-opening 122.

It is therefore a technical solution that is relatively simple to implement and that ensures optimal retention of the cap 141 in the through-opening 122 without hindering the movement of the latter.

In this example, the elastic element 142 is therefore disposed between the locking washer 151 and the peripheral edge 141c of the cap 141 so as to be able to push the cap 141 from the retracted position to the deployed position, for example when the cabinet door 16 is opened.

In this example, the holding means 15 optionally comprise an additional washer 152 interposed between the locking washer 151 and the elastic element 142 such that the force of the elastic element 142 is not applied directly against the locking washer 151.

With reference to the switch 14 of the second exemplary embodiment illustrated in FIGS. 6 and 7, the cap 141 has a switching pin 141d which extends from the peripheral edge 141c in a direction opposite to the main part 141a. In other words, the switching pin 141d extends generally coaxially with the main part 141a, but on the other side of the edge 141c. The switching pin 141d is configured to pass through the holding means 15 (and in particular the locking washer 151) so as to then cooperate with the electrical contactor 143 when the cap 141 is in the retracted position (as illustrated in FIG. 7).

The systems and devices described herein may include a controller or a computing device comprising a processing unit and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

Claimed is:

1. An electrical installation for an aircraft, the electrical installation comprising:
an electrical distribution bar configured to be fastened to a support of an electrical cabinet;
a printed circuit comprising a first male or female electrical connection element; and
a current transformer comprising:
a body comprising a through-opening, the electrical distribution bar configured to pass through the through-opening;
fastening means configured to fasten the body to the support; and
a second female or male electrical connection element configured correspondingly to the first male or female electrical connection element and being disposed in the through-opening and electrically connected to the first male or female electrical connection element of the printed circuit; and,
an item of equipment configured to be electrically connected to the electrical distribution bar.

2. The electrical installation as claimed in claim 1, wherein the current transformer further comprises a switching device configured to detect whether the item of equipment is electrically connected to the electrical distribution bar.

3. The electrical installation as claimed in claim 2, wherein the switching device comprises a mechanical switch and an electrical contactor secured to the second female or male electrical connection element,
wherein the mechanical switch comprises:
a cap mounted movably in translation in the through-opening in the body between a retracted position, corresponding to a position in which the item of equipment is electrically connected to the electrical distribution bar, and a deployed position, corresponding to a position in which the item of equipment is not electrically connected to the electrical distribution bar, the cap comprising a switching pin; and,
an elastic element secured to the body and the cap, the elastic element configured to move the cap from the retracted position to the deployed position when the item of equipment is not electrically connected to the electrical distribution bar; and
wherein the electrical contactor is configured to cooperate with the switching pin of the cap when the cap is in the retracted position so that the electrical contactor is then configured to transmit an electrical signal to a control unit for controlling an electrical power supply of the electrical distribution bar indicating an electrical connection of the item of equipment to the electrical distribution bar.

4. The electrical installation as claimed in claim 2, wherein the switching device comprises a mechanical switch and a proximity sensor disposed in the body and in proximity to the through-opening and the first male or female electrical connection element,
wherein the mechanical switch comprises:
a cap mounted movably in translation in the through-opening in the body between a retracted position, corresponding to a position in which the item of equipment is electrically connected to the distribution bar, and a deployed position, corresponding to a position in which the item of equipment is not electrically connected to the electrical distribution bar; and,
an elastic element secured to the body and the cap, the elastic element configured to move the cap from the retracted position to the deployed position when the item of equipment is not electrically connected to the electrical distribution bar; and
wherein the proximity sensor is configured to detect when the cap is in the retracted position and is further configured to transmit information about an electrical connection of the item of equipment to a control unit for controlling an electrical power supply of the electrical distribution bar.

5. The electrical installation as claimed in claim 4, wherein the mechanical switch further comprises holding means configured to hold the cap in the through-opening.

6. The electrical installation as claimed in claim 5, wherein the cap comprises a main part of tubular shape, a first end of which comprises a peripheral edge received in the through-opening, wherein the through-opening comprises, at a first end, a peripheral slot and, at a second end, a peripheral shoulder,
wherein the holding means comprise a locking washer disposed in the peripheral slot, and wherein the peripheral edge of the cap is configured to move between the peripheral shoulder of the through-opening and the locking washer, and
wherein the cap comprises, when in use, a switching pin which extends from the peripheral edge in a direction opposite to the main part, the switching pin configured configured to pass through the holding means so as to cooperate with an electrical contactor of the cap when the cap is in the retracted position.

7. The electrical installation as claimed in claim 6, wherein the elastic element is disposed between the locking washer and the peripheral edge of the cap.

8. An aircraft comprising:
at least one electrical installation as claimed in claim 1.
